(19) United States
(12) Patent Application Publication
(10) Pub. No.: US 2009/0245311 A1
(43) Pub. Date: Oct. 1, 2009

(54) PROCESS FOR PRODUCING NITRIDE SEMICONDUCTOR LASER, AND NITRIDE SEMICONDUCTOR LASER

(75) Inventors: Kyozo KANAMOTO, Tokyo (JP); Katsuomi Shiozawa, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: MITSUBISHI ELECTRIC CORPORATION, Chiyoda-ku (JP)

(21) Appl. No.: 12/397,783

(22) Filed: Mar. 4, 2009

(30) Foreign Application Priority Data
Mar. 5, 2008 (JP) 2008-054548

(51) Int. Cl. H01S 5/323; H01L 21/26

(52) U.S. Cl. 372/45.012; 438/47; 257/E21.328

(57) ABSTRACT

Provided are a process for producing a nitride semiconductor laser that is a process applied to materials wherein a diffusion of an impurity is not easily attained, such as nitride semiconductor material, and substituted for any process including the step of local diffusion of an impurity, which has been hitherto carried out for GaAlAs based or AlGaInP based semiconductors, and that is a process which is effective, high in precision, and suitable for mass production; and a nitride semiconductor laser produced by this process. The nitride-semiconductor-producing process of the present invention includes the steps of: preparing a substrate having an MQW active layer made of a nitride semiconductor containing In; irradiating a vicinity of a light-emitting end face of the multiquantum well active layer, or a planned region of the light-emitting end face selectively with a laser beam; and performing heating treatment after the laser-irradiating step.

### BACKGROUND OF THE INVENTION

1. Field of the Invention

The present invention relates to a process for producing a nitride semiconductor laser, and a nitride semiconductor laser.

2. Description of the Background Art

In realization of an action of a high power over 200 mW in a semiconductor laser diode, end face breakdown caused by absorption of light to an end face thereof becomes a problem. In order to prevent this problem in a red laser diode, a window structure has been hitherto adopted wherein a band gap of an end face thereof is widened, thereby decreasing light absorption. It is expected that an equivalent or similar window structure is effective for heightening the power of nitride semiconductor lasers.

An ordinary method for widening the band gap is generally a method of disordering an end region of a multiquantum well (MQW) layer, which is an active layer, so as to be made into a mixed crystal state, thereby yielding a window region having a higher band gap than a middle region. In nitride semiconductor lasers, a similar method is also suggested.

For disordering the window region selectively in these methods, the following processes in the related art are known: a process of attaining the disordering by solid-layer-diffusion (Japanese Patent Application Laid-Open No. 2006-140387 (Patent Document 1)), a process of attaining the disordering by ion implantation and annealing (Japanese Patent Application Laid-Open No. 2006-229210 (Patent Document 2)), and the like. Japanese Patent Application Laid-Open No. 2006-229210 discloses a process of irradiating a laser beam, as auxiliary means for attaining local heating at the time of the annealing, locally. Moreover, known is an example in the related art (Japanese Patent Application Laid-Open No. 2007-214361 (Patent Document 3)) wherein the distribution of an impurity is regulated regardless of the processes.

The following other examples in the related art are also known: a process of exposing a resonator end face of a nitride-based Group III-V compound semiconductor containing In to an atmosphere containing H2, thereby eliminating In from an end region thereof to make the band gap large (Japanese Patent Application Laid-Open No. 2006-147814 (Patent Document 4)), and a process of irradiating such a resonator end face with a laser beam, thereby eliminating In to make the band gap large (Japanese Patent Application Laid-Open No. 2006-147815 (Patent Document 5)).

As a process using no local diffusion of an impurity from the outside, or the like, known is an example of attaining selective disordering by the generation of defects by effect of laser pulses (IEEE Journal of Quantum Electronics, Vol. 33, No. 1 (1997) p. 45).

However, any one of Patent Documents 1 to 3 is related to a process of diffusing an impurity locally into an MQW active layer, thereby lowering a mutual diffusion temperature of constituting elements to attain selective disordering; thus, in a case where the diffusion of an impurity is not easy as in a nitride semiconductor, the formation thereof is difficult. Moreover, the diffusion of an impurity causes an increase in carriers. As a result, light absorption is increased. Thus, there is produced an effect incompatible with a decrease in light absorption, which is a primary purpose of the formation of a window.

Patent Documents 4 and 5 relate to a nitride semiconductor, and are each directed to a process including the step of eliminating In from an end face to change the composition. However, the process has a problem that the step needs to be performed after the formation of an end face so that the process is made complicated so as to be unsuitable for mass production. IEEE Journal of Quantum Electronics, Vol. 33, No. 1 (1997) p. 45 refers to an InGaAs—InGaAsP based MQW; however, the document does not describe the formation of a window structure of a nitride semiconductor.

### SUMMARY OF THE INVENTION

An object of the present invention is to provide a process for producing a nitride semiconductor laser that is a process applied to materials in which a diffusion of an impurity is not easily attained, such as nitride semiconductor material, and substituted for any process including the step of local diffusion of an impurity, which has been carried out for GaAlAs based or AlGaInP based semiconductors in the related art, and that is a process which is effective, high in precision, and suitable for mass production; and a nitride semiconductor laser produced by the producing process.

The process for producing a nitride semiconductor laser according to the present invention includes first to third steps described below. The first step is a step of preparing a substrate having a multiquantum well (MQW) active layer including a nitride semiconductor containing In. The second step is a step of irradiating a vicinity of a light-emitting end face of the multiquantum well active layer, or a planned region of the light-emitting end face selectively with a laser beam. The third step is a step of performing heating treatment after the laser-irradiating step.

According to the present invention, local defects are generated by effect of the laser beam and further the MQW active layer is selectively disordered by the heating, so that disordering can be attained without performing any impurity-diffusion, which is said to be not easily attained for nitride semiconductors. Additionally, an end face window structure can be formed by a producing process that does not cause a property-deterioration generated when the whole is subjected to high-temperature treatment for a long period of time in order to diffuse an impurity, a problem that absorption of light into an end face is increased by an unnecessary introduction of an impurity, or other problems. For this reason, a highly reliable and high-power nitride semiconductor laser can be obtained.

Moreover, in a case where the laser beam is selectively scanned onto the MQW active layer in the substrate before the formation of the end face, a local window structure can be formed. Thus, a conventional patterning step based on transfer necessary for diffusion or implantation becomes unnecessary. As a result, the productivity is improved, and costs can also be reduced.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic view of a nitride semiconductor laser according to the present invention when the laser is viewed from a light-emitting end face thereof.

FIG. 2 is a schematic view illustrating a cross section of the nitride semiconductor laser according to the present invention.

FIG. 3 is a view illustrating a substrate after epitaxial growth thereof in the nitride-semiconductor-producing process according to the present invention.

FIG. 4 is an enlarged view of a portion of the substrate illustrated in FIG. 3.

FIG. 5 is a view illustrating a laser-irradiating step in the nitride-semiconductor-producing process according to the present invention.

FIG. 6 is a thermal treatment step in the nitride-semiconductor-producing process according to the present invention.

FIG. 7 is a view illustrating a nitride semiconductor laser after completion of the nitride-semiconductor-producing process according to the present invention.

FIG. 8 is a schematic top view of a one-chip-corresponding area of the nitride semiconductor laser in a middle of the nitride-semiconductor-producing process according to the present invention when the area is viewed from above.

FIG. 9 is a schematic view of the one-chip-corresponding area of the nitride semiconductor laser in the middle of the nitride-semiconductor-producing process according to the present invention when the area is viewed from an oblique direction.

FIG. 10 is a graph showing a relationship between an irradiating period of laser pulse power at individual laser powers and an emission wavelength of an MQW active layer.

FIG. 11 is a graph showing a relationship between a thermal treatment period at individual thermal treatment temperatures and the emission wavelength.

FIG. 12 is a graph showing a change in a p-type impurity concentration and a change in band gap energy in the MQW active layer of a nitride semiconductor laser according to the present invention.

FIG. 13 is a graph showing a current-to-light-power property of a nitride semiconductor laser having a window structure related to the present invention, and that of a nitride semiconductor laser having no window structure.

### DESCRIPTION OF THE PREFERRED EMBODIMENTS

Hereinafter, the present invention will be specifically described with reference to the drawings.

### First Embodiment

### Structure

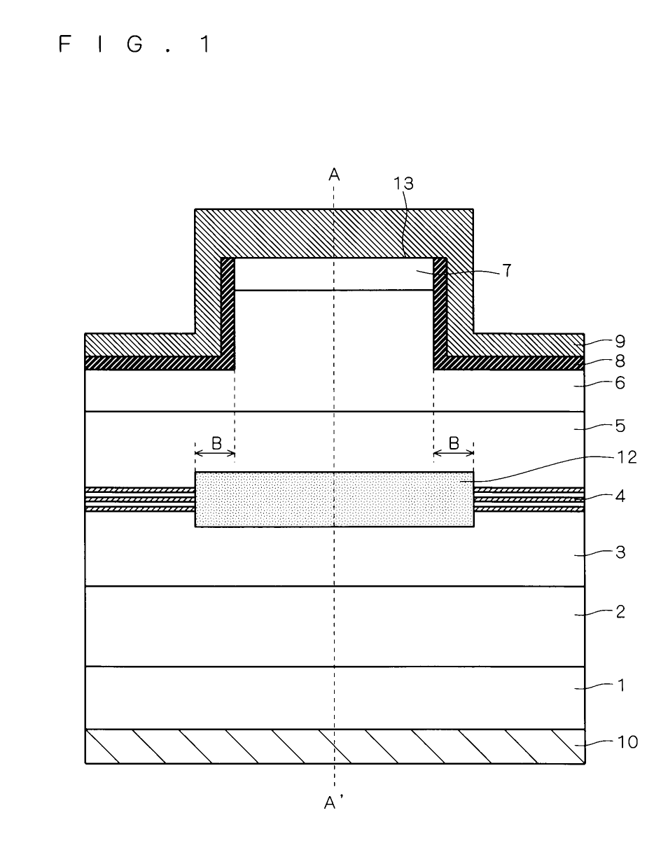

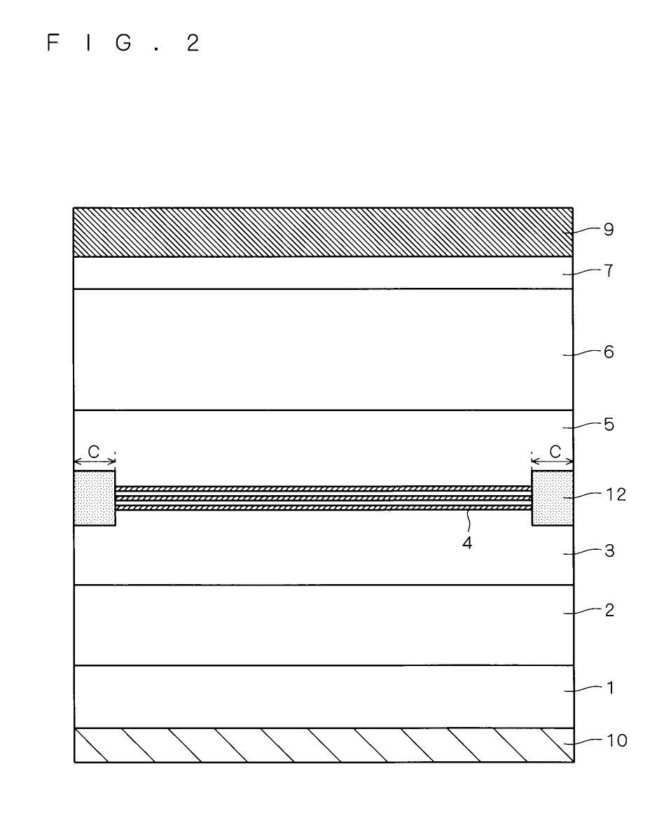

With reference to FIGS. 1 and 2, a structure of a nitride semiconductor laser related to the present embodiment will be described. FIG. 1 is a schematic view of the nitride semiconductor laser, which is produced by use of a producing process according to the present embodiment, when the laser is viewed from a light-emitting end face side thereof. FIG. 2 is a schematic view of the nitride semiconductor laser illustrated in FIG. 1 when an A-A′ cross section of the laser is viewed from a side thereof.

This semiconductor laser is, for example, a gallium nitride semiconductor laser from which a blue laser beam is generated. As illustrated in FIG. 2, in the A-A′ cross section of the nitride semiconductor laser illustrated in FIG. 1, the following are laminated on an n-type GaN substrate 1, which is an n-type nitride semiconductor substrate: an n-type AlGaN clad layer 2; an n-type GaN guide layer 3; an MQW active layer (multiquantum well active layer) 4 made of InGaN/GaN; a p-type GaN guide layer 5; a p-type AlGaN clad layer 6; a p-type GaN contact layer 7; and a p-electrode 9. An n electrode 10 is formed on a rear face of the n-type GaN substrate 1.

Disordered regions 12, each having a window structure wherein the MQW active layer 4 is made into a mixed crystal state so that a widened band gap is generated, are formed in the vicinities of end faces of the MQW active layer 4. Thus, a concentration of the p-type impurity present in the MQW active layer 4 is made lower in the vicinities of the end faces, for emitting light, than in any other region, and further the band gap of the MQW active layer 4 is widened in the vicinities of the light-emitting end faces than in any other region.

As illustrated in FIG. 1, on the light-emitting end face sides, the disordered regions 12 are each formed except end (or edge) regions of the MQW active layer 4. Moreover, a ridge waveguide (ridge) 13 made of an upper region of the p-type AlGaN clad layer 6 and the p-type GaN contact layer 7 is formed. An insulating film 8 is formed in regions extending from side faces of the ridge waveguide 13 to the upper face of the p-type AlGaN clad layer 6 connected to the lower portions of the ridge waveguide side faces. Furthermore, the p-electrode 9 is located to cover the upper face of the ridge waveguide 13 and the insulating film 8.

As illustrated in FIGS. 1 and 2, on each of the light-emitting end face sides, the disordered region 12 is formed in such a manner that a distance B of the disordered region 12 from the side faces of the ridge waveguide 13 toward the outside is about 5 μm and a distance C thereof from the corresponding light-emitting end face toward the inside is also about 5 μm.

### (Producing Process)

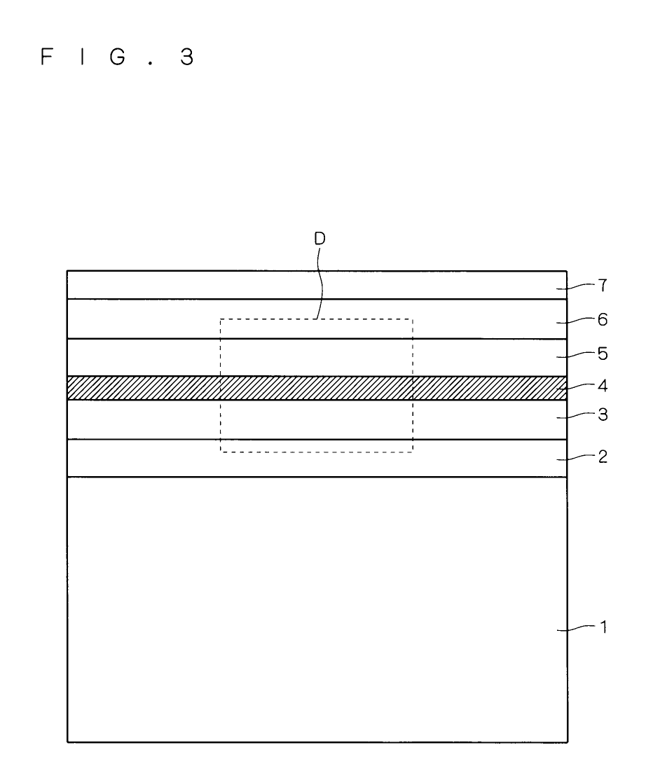

With reference to FIGS. 3 to 7, a process for producing the nitride semiconductor laser according to the present embodiment, in particular, a wafer process flow related to formation of the windows 12 will be described.

FIG. 3 illustrates a substrate after epitaxial growth thereof. As illustrated in FIG. 3, MOCVD is first used to grow individual necessary layers onto a GaN substrate to prepare a wafer-form substrate made of a nitride semiconductor and having an MQW active layer 4 doped with an impurity, In, in an amount of not less than 1E18 cm⁻³. In a process for working this wafer, marks necessary for transfer will be formed by irradiation with a laser beam.

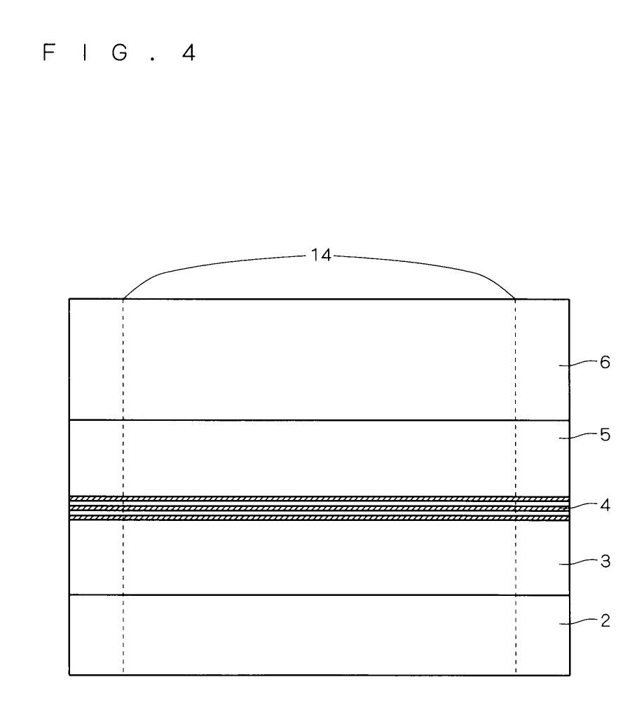

FIG. 4 is an enlarged view of a D region illustrated in FIG. 3. Reference numeral 14 denotes a planned region 14 of one of light-emitting end faces, which is to be one of the light-emitting end faces in the nitride semiconductor laser. FIG. 5 illustrates the wafer in a laser-irradiating step. A pulse laser beam is scanned onto the upper face of the wafer from the above thereof to form the marks, which are overlapping marks, and further a pulse laser beam is scanned and the vicinity of each of the light-emitting end faces or each of the planned regions 14 of the light-emitting end faces is irradiated selectively with the pulse laser beam. In other words, the wafer which has the MQW active layer 4 of the nitride semiconductor containing In is locally irradiated with a laser beam 16 condensed through a lens 15 from the upper face thereof, so as to produce defect-formed regions 11 selectively. The step of irradiating the laser beam 16 at this time is conducted in an atmosphere containing nitrogen.

In the present embodiment, the following conditions are realized in the production of the semiconductor laser, which is a laser for emitting a wavelength of 405 nm, by selecting a laser beam having an emission wavelength of 355 nm from Nd:YVO4 lasers that are excited by a laser diode: the selected laser beam is absorbed in the MQW active layer 4, which has a band gap corresponding to a wavelength of 405 nm, and the n-type GaN guide layer 3 and the p-type GaN guide layer 5, which each have a band gap corresponding to a wavelength of 357 nm, but is neither absorbed in the n-type AlGaN clad layer 2 nor the p-type AlGaN clad layer 6, which has a band gap corresponding to a wavelength of 340 nm. In short, the energy of the irradiated laser beam is lower than the band gap energy of the n-type AlGaN clad layer 2 and the p-type AlGaN clad layer 6, and is higher than the band gap energy of the MQW active layer 4.

The GaN material has a high thermal conductivity. Thus, in order to cause heat not to be conducted into larger or wider regions than required regions, the laser beam is made into a pulse form, the width of the pulses is made narrow and further the power density of the light is made higher. For example, the pulse width is set to 20 ns and the repeating frequency is set to 60 kHz so that the period is made long, whereby the laser beam causes the temperature of the material to be raised only when the material is irradiated with the laser beam. In this way, only regions that are irradiated with the laser beam can be made into a high temperature state.

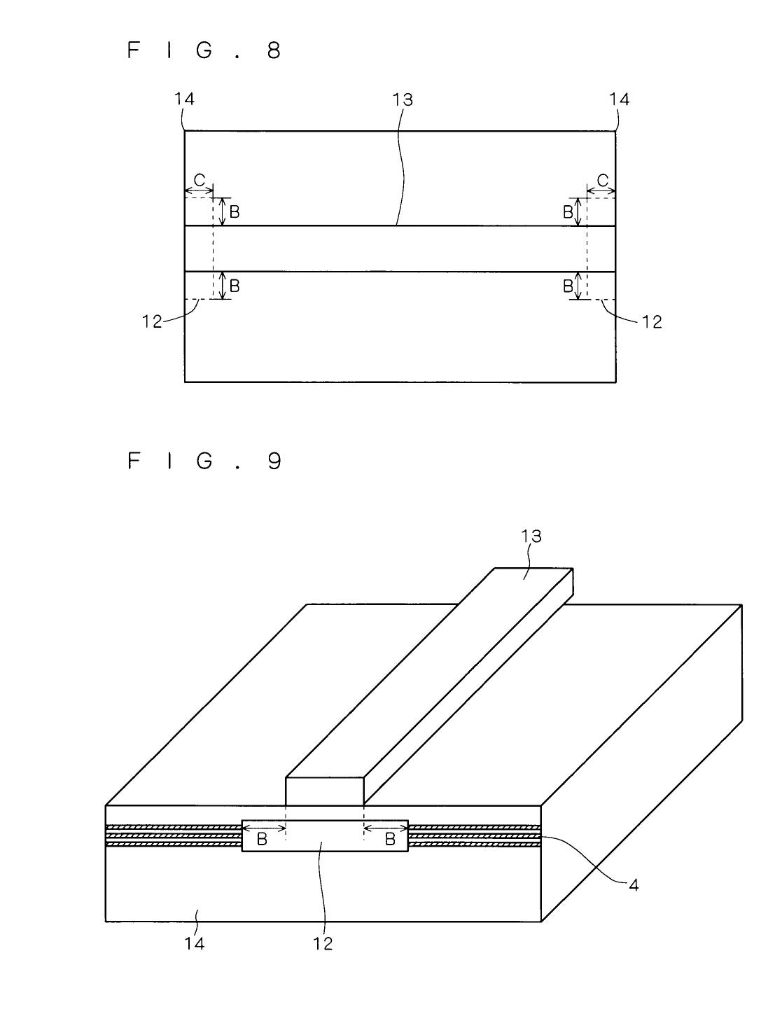

When the temperature of the MQW active layer 4 and the layers containing the GaN in the vicinities of the layer 4 is raised by the irradiation of the laser beam, the highest temperature of the layers is controlled to not more than 1600° C. For this purpose, the laser power and the irradiating period are optimized. FIG. 10 shows a relationship between the irradiating period of the laser pulse power and the emission wavelength of the MQW active layer 4 when the laser power is set to 1 mW, 10 mW and 50 mW, respectively. As a result of the optimization, the following conditions are set in this embodiment: a laser power of 50 mW, a pulse width of 20 ns, a repeating frequency of 60 kHz, a beam diameter of 2 μm, and a scanning speed of 5 mm/sec.

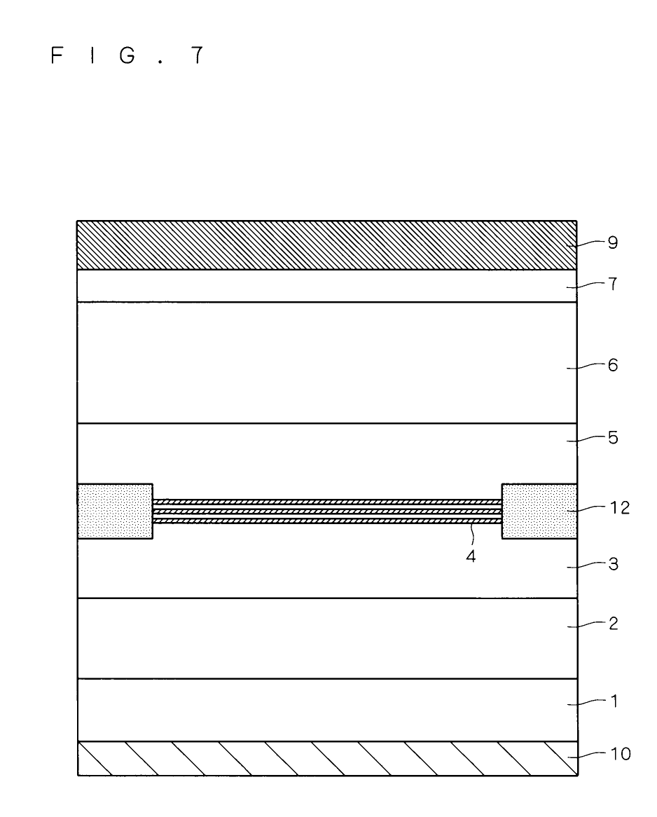

About each of regions where the laser beam is to be irradiated, the emission efficiency of the nitride semiconductor laser lowers if the region enters the inside too deeply from the corresponding light-emitting end face. As a result, a threshold value increases. On the other hand, if the region enters the inside too shallowly, a sufficient window effect is not obtained. Moreover, if a breadth of the region from side faces of the ridge waveguide 13 toward the outside is made small, a shape of the emitted beam is deteriorated. However, if the breadth is made too large, a period of scanning time of the laser beam becomes long so that the producing process period is increased. Thus, it is preferred that each of the regions to be irradiated with the laser beam has a distance of not less than 2 μm and not more than 10 μm from the side faces of the ridge formed in the substrate or the side faces of a planned region of the ridge toward the outside, and further has a distance of not less than 2 μm and not more than 10 μm from the corresponding light-emitting end face or the planned region of the light-emitting end face toward the inside. FIG. 8 illustrates a top surface of a one-chip corresponding region of the nitride semiconductor laser in the middle of the process after the formation of the ridge, and FIG. 9 illustrates an outline thereof when the nitride semiconductor laser is viewed from an oblique direction. As illustrated in FIGS. 8 and 9, each of the regions to be irradiated with the laser beam is made to have a distance C of 5 μm from the planned region 14 of the corresponding light-emitting end face toward the inside of the element, and have a distance B of 5 μm from the side faces of the ridge toward the outside. The above-mentioned regions is scanned and then irradiated with the laser beam.

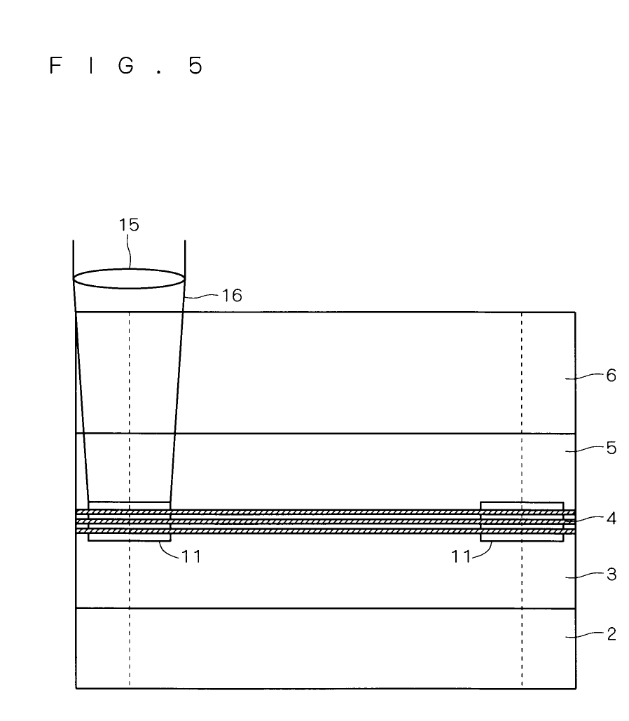

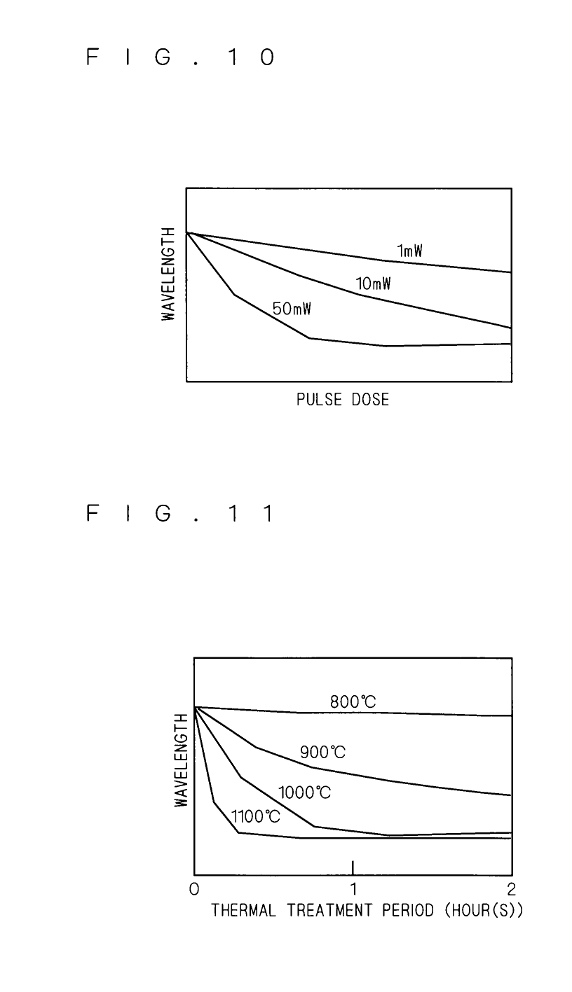

FIG. 6 illustrates the wafer in a heating treatment step. After the irradiation of the laser beam, in order to disorder the MQW active layer 4, the wafer is thermally treated in an atmosphere of nitrogen gas to form disordered regions 12. In short, the wafer is subjected to heating treatment in an atmosphere containing nitrogen gas. At this time, although not illustrated, an SiN film is formed on the whole of the surface by CVD in order to attain surface-protection for preventing the elimination of nitrogen from the crystal surface through the thermal treatment. FIG. 11 shows a relationship between the thermal treatment period and the emission wavelength of the MQW active layer 4 when the thermal treatment temperature is set to 800° C., 900° C., 1000° C., and 1100° C., respectively. The heating treatment is preferably conducted at a temperature of not less than 1000° C. and not more than 1400° C. Optimally, the heating treatment is conducted at 1100° C. in an N₂ atmosphere for 2 minutes by use of an RTA apparatus. The heating treatment is conducted in a gas atmosphere containing any one of N₂, ammonia, and dimethylhydrazine.

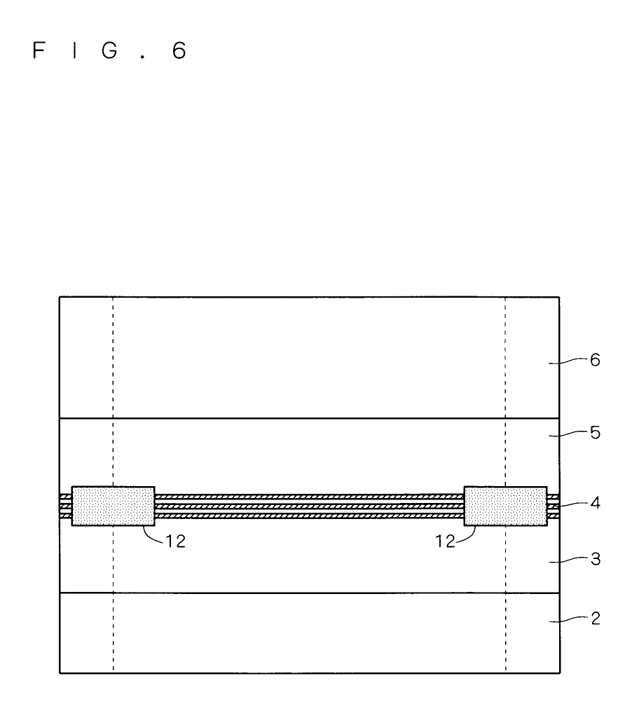

The SiN film is removed by BHF. Thereafter, in accordance with an ordinary laser diode process flow, the nitride semiconductor laser is formed; thus, a detailed description thereof is not given herein. After the completion of the ordinary process, a nitride semiconductor laser illustrated in FIG. 7 is completed.

### (Advantageous Effects)

In a region irradiated with a pulse laser, lattice defects projected from original lattice positions are generated when a high energy is applied to crystal lattices in the region. When such lattice defects are present, mutual diffusion of atoms is easily caused. Thus, by thermal treatment conducted after the laser beam irradiation, mutual diffusion, for which high temperature is originally required, can be selectively generated only in a vicinity of the lattice defects. In other words, disordering of a nitride semiconductor without requiring any impurity diffusion is made possible by generating local defects by a pulse laser beam and attaining selective disordering of the MQW active layer 4 by heating although the disordering is said to be difficult.

In this way, the InGaN/GaN-MQW active layer 4 is disordered by mutual diffusion, thereby being turned to InGaN having a mixed crystal composition, so that the band gap decided by the quantum well level is turned to a band gap of the mixed crystal. As a result, the band gap can be substantially widened. Moreover, end face window structures can be formed by a process which does not cause problems as described in the following: the property is deteriorated in a case where the whole is subjected to high-temperature treatment for a long period of time in order to attain impurity-diffusion; and the absorption of light into the end faces is increased by an unnecessary impurity-introduction. As a result, highly reliable and high power nitride semiconductor laser can be obtained.

For nitride semiconductors, a treatment at a high temperature of not less than 1000° C. is required. Furthermore, unless a treatment for compensating for the elimination of nitrogen during the high-temperature treatment is conducted, the crystal deteriorates. For this reason, it is important to control the treatment temperature and the atmosphere.

About the nitride semiconductor laser formed as described above, window structures wherein no light loss is generated can be realized by a structure having the MQW active layer 4, which has a p-type impurity concentration made lower in the vicinity of each of the light-emitting end faces than in any other region and has a band gap made wider in the vicinity of each of the light-emitting end faces than in any other region. As a result, the power of the laser beam can easily be made high.

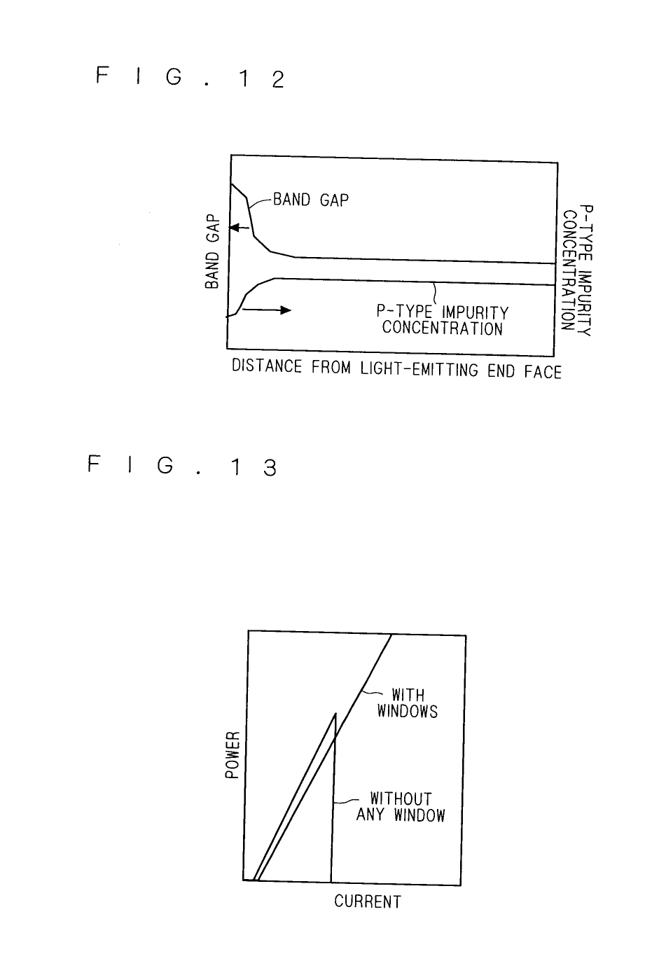

FIG. 12 shows the impurity distribution of the formed nitride semiconductor laser and the band gap energy distribution thereof. The average p-impurity concentration in the MQW active layer 4 becomes lower nearer to each of the light-emitting end faces, and simultaneously the band gap energy becomes larger nearer to each of the light-emitting end faces. For this reason, window structures wherein light absorption is less generated can be formed in the end faces. FIG. 13 shows the current-light power property of the nitride semiconductor laser. It can be understood that the upper limit of the power against end face breakdown is improved by the window structures.

By use of a laser beam having an energy lower than the band gap energy of the n-type AlGaN clad layer 2 and the p-type AlGaN clad layer 6 and higher than the band gap energy of the MQW active layer 4, a layer wherein light absorption is mainly caused is limited to the MQW active layer 4 so that light can be restrained from being absorbed in unnecessary regions. Thus, a deterioration based on the window-forming process can be restrained as much as possible. By scanning the laser beam selectively inside the MQW active layer 4 in the substrate before the end faces are formed, local window structures can be formed. Thus, a conventional patterning step based on transfer necessary for diffusion or implantation becomes unnecessary. As a result, productivity is improved, and costs can also be decreased.

Use of a pulse laser having an emission wavelength of 355 nm as the laser beam to be irradiated makes it possible to realize a matter that light is neither absorbed with ease into the n-type AlGaN clad layer 2 nor the p-type AlGaN clad layer 6, and local heating is attained. Thus, a deterioration based on the window-forming process can be restrained into a minimum level. Moreover, by doping the MQW active layer 4 with an impurity in an amount of not less than 1E18 cm⁻³, the MQW active layer 4 can easily be made into a mixed crystal state so that a necessary treatment temperature can be lowered. Thus, a deterioration based on the window-forming process can be restrained into a minimum level.

Furthermore, by scanning the regions to be irradiated with the laser beam, the laser-irradiated regions can be optimized. Thus, a nitride semiconductor giving an excellent laser beam shape can be yielded. Specifically, about the size of each of the laser-irradiated regions, the distance thereof from both sides of the ridge waveguide 13 toward the outside is set into the range of 2 μm to 10 μm and the distance thereof from the corresponding laser end face toward the inside is set into the range of 2 μm to 10 μm, thereby making it possible to yield a nitride semiconductor laser excellent in property. Additionally, the irradiation of the laser beam into unnecessary regions is restrained so that the processing period can be made short.

In this case, the treatment of irradiating the laser beam locally is conducted in an atmosphere containing nitrogen, thereby restraining elimination of nitrogen from the wafer surface based on a local temperature rise at the time of the laser beam irradiation. Furthermore, when the heating treatment is conducted in a gas atmosphere containing any one of N₂, ammonia and dimethylhydrazine, the elimination of nitrogen from the wafer surface is restrained at the time of the thermal treatment. By conducting the heating treatment at a temperature of not less than 1000° C. and not more than 1400° C., the disordering of the MQW active layer 4 by the thermal treatment is effectively attained and further a deterioration of the wafer by high temperature is restrained.

### Second Embodiment

### Structure

In the present embodiment, irradiation of a laser beam is not conducted in a scanning manner but is conducted at intervals of 1 μm. Thus, the state distribution of the disordered regions 12 illustrated in FIGS. 1 and 2, which is affected by the difference between the manners, may be somewhat different from that in the first embodiment. However, when the number of pulse-irradiating times in each of points in the irradiated regions is set into the same degree or a similar degree, a substantially similar state distribution is obtained. The others in the structure are the same as in the first embodiment; thus, a detailed description thereof is not given herein.

### (Producing Process)

In the present embodiment, the irradiation of the pulse laser beam illustrated in FIG. 5 is not conducted in a scanning manner, but is conducted at intervals of 1 μm relative to a beam diameter of 2 μm. The number of the pulse-irradiating times in each of points in the irradiated regions is set into the same degree or a similar degree in the scanning manner described in the first embodiment. The others in the process are similar to the first embodiment; thus, a detailed description thereof is not given herein.

### (Advantageous Effects)

An apparatus for irradiating the laser beam needs not to have a scanning function or a scanning speed adjusting function. Thus, for the production of a nitride semiconductor laser having performances of the same degree, costs can be decreased.

### Third Embodiment

### Structure

In the present embodiment, the disordered regions 12 of the nitride semiconductor laser, that is, the window structures thereof are formed by use of two-photon absorption process. As compared with the case of using one-photon absorption process described in the first embodiment, boundary regions between the regions and the non-disordered region, sharper structures are generated. The others in the structure are the same as in the first embodiment; thus, a detailed description thereof is not given herein.

### (Producing Process)

In the first embodiment, the wavelength of the laser beam to be irradiated is set to a wavelength absorbed in the MQW active layer 4; however, in the present embodiment, an infrared laser beam having a wavelength of 800 nm is used, and irradiation thereof is performed using two-photon absorption process. In other words, the energy of the pulse laser beam to be irradiated is made lower than the band gap energy of the MQW active layer 4, which is a band gap corresponding to a wavelength of 405 nm and is further made higher than a half of the band gap energy, and two-photon absorption process is used. At this time, a focus of the laser beam is adjusted into a vicinity of the MQW active layer 4.

The others in the process are similar to the first embodiment; thus, a detailed description thereof is not given herein.

### (Advantageous Effects)

In order to cause selective disordering with a high precision in forming of the disordered regions 12, it is necessary to cause the laser beam irradiation to have selectivity in a transverse direction and selectivity in a layer direction. However, the method using one-photon absorption described in the first embodiment is insufficient in precision.

In the present embodiment, the energy of the pulse laser beam to be irradiated is made smaller than the band gap energy of the MQW active layer 4 and further made larger than the half of the band gap energy, and the focus of the laser beam is adjusted into the vicinity of the MQW active layer 4 to use two-photon absorption process, whereby the size of spots where light absorption is caused can be set to the wavelength or less. Thus, sharp windows can be precisely formed. For this reason, the power of the nitride semiconductor laser can be made high without deteriorating the property of the laser.

While the invention has been shown and described in detail, the foregoing description is in all aspects illustrative and not restrictive. It is therefore understood that numerous modifications and variations can be devised without departing from the scope of the invention.

What is claimed is:

1. A process for producing a nitride semiconductor laser, comprising the steps of:
preparing a substrate having a multiquantum well (MQW) active layer formed by a nitride semiconductor containing In;
irradiating a vicinity of a light-emitting end face of said multiquantum well active layer, or a planned region of the light-emitting end face selectively with a laser beam; and
performing heating treatment after the laser-irradiating step.

2. The process for producing a nitride semiconductor laser according to claim 1, wherein said laser-irradiating step is conducted in an atmosphere containing nitrogen.

3. The process for producing a nitride semiconductor laser according to claim 1, wherein said heating treatment step is conducted in an atmosphere containing nitrogen.

4. The process for producing a nitride semiconductor laser according to claim 2, wherein any one selected from the group consisting of N₂, ammonia and dimethylhydrazine is used for said nitrogen-containing atmosphere.

5. The process for producing a nitride semiconductor laser according to claim 3, wherein any one selected from the group consisting of N₂, ammonia and dimethylhydrazine is used for said nitrogen-containing atmosphere.

6. The process for producing a nitride semiconductor laser according to claim 1, wherein said heating treatment is conducted at a temperature not less than 1000° C. and not more than 1400° C.

7. The process for producing a nitride semiconductor laser according to claim 1, wherein said substrate has a clad layer, and
energy of said irradiated laser beam is lower than band gap energy of said clad layer and is higher than band gap energy of said multiquantum well active layer.

8. The process for producing a nitride semiconductor laser according to claim 7, wherein said irradiated laser beam is a pulse laser having an emission wavelength of 355 nm.

9. The process for producing a nitride semiconductor laser according to claim 1, wherein the energy of said irradiated laser beam is lower than the band gap energy of said multiquantum well active layer and is higher than a half of the band gap energy of said multiquantum well active layer, and
in said laser-irradiating step, two-photon absorption process is used.

10. The process for producing a nitride semiconductor laser according to claim 1, wherein said multiquantum well active layer is formed so as to be doped with an impurity in an amount of not less than 1E18 cm⁻³.

11. The process for producing a nitride semiconductor laser according to claim 1, wherein said laser-irradiating step is performed while a region to be irradiated with the laser beam is scanned.

12. The process for producing a nitride semiconductor laser according to claim 1, wherein in connection with said laser-irradiating step, a region to be irradiated with the laser beam has a distance of not less than 2 μm and not more than 10 μm from side faces of a ridge to be formed in said substrate or side faces of a planned region of the ridge toward an outside of the laser, and further has a distance of not less than 2 μm and not more than 10 μm from said light-emitting end face or said planned region of the light-emitting end face toward an inside of the laser.

13. A nitride semiconductor laser which is produced by a nitride-semiconductor-laser-producing process comprising the steps of:
preparing a substrate having a multiquantum well (MQW) active layer formed by a nitride semiconductor containing In;
irradiating a vicinity of a light-emitting end face of said multiquantum well active layer, or a planned region of the light-emitting end face selectively with a laser beam; and
performing heating treatment after the laser-irradiating step,
wherein a concentration of a p-type impurity present in said multiquantum well active layer is made lower in the vicinity of said light-emitting end face than in any other region, and further a band gap of said multiquantum well active layer is widened in the vicinity of said light-emitting end face than in any other region.
